(19) United States
(12) Patent Application Publication
(10) Pub. No.: US 2026/0190288 A1
(43) Pub. Date: Jul. 2, 2026

(54) COOLING DEVICE FOR POWER MODULE

(71) Applicants: HYUNDAI MOTOR COMPANY, SEOUL (KR); KIA CORPORATION, SEOUL (KR)

(72) Inventors: Jun Suk Yoo, Hwaseong-si (KR); Han Geun Jang, Hwaseong-si (KR); Hun Kong, Hwaseong-si (KR); Seong Hyeon Cho, Hwaseong-si (KR); Jae Sung Mo, Hwaseong-si (KR); Jong Kyong Lim, Hwaseong-si (KR); Sung Yong Park, Hwaseong-si (KR)

(73) Assignees: HYUNDAI MOTOR COMPANY, SEOUL (KR); KIA CORPORATION, SEOUL (KR)

(21) Appl. No.: 19/224,272

(22) Filed: May 30, 2025

(30) Foreign Application Priority Data
Jan. 2, 2025 (KR) 10-2025-0000523

(51) Int. Cl. H05K 7/20

(52) U.S. Cl. CPC H05K 7/20272; H05K 7/20409; H05K 7/209; H05K 7/20927

(57) ABSTRACT

Disclosed is a cooling device for a power module that reduces a heat resistance and increases a cooling efficiency of a direct cooling method. The cooling device includes a plurality of power semiconductor elements mounted on an upper surface of a heat dissipating board. The power module may include a manifold having an inlet and an outlet, in which a heat dissipating space part, an upper portion of which is exposed to an outside, is formed, in which a flow channel, through which a cooling fluid flows, is formed in an interior thereof, and having a channel passage, in which a portion of the flow channel passing through the heat dissipating space part is open to an upper side of the heat dissipating space part. The flow channel may be formed to become narrower from the inlet toward the outlet of the manifold in the heat dissipating space part.

### CROSS-REFERENCE TO RELATED APPLICATION(S)

This application claims the benefit of priority to Korean Patent Application No. 10-2025-0000523, filed in the Korean Intellectual Property Office on Jan. 2, 2025, the entire contents of which are incorporated herein by reference.

### TECHNICAL FIELD

The present disclosure relates to a cooling device for a power module having an improved cooling performance.

### BACKGROUND

In general, an inverter of an electric vehicle (xEV) is a power conversion device that converts energy stored in a high voltage battery into a form that is suitable for motor control. Competition of companies is intensifying to secure vehicle driving performance, and for this purpose, power density of an inverter and the number of power modules used are increasing.

As the power density of the inverter increases, the amount of heat generated by the power module increases, and the temperature of the power module element is raised. If the temperature of the power module is raised above a suitable limit, it is possible that the power module may be damaged due to a fire.

Accordingly, the power module has to be cooled through a cooling system, and to improve cooling performance, a supply temperature of a cooling fluid has to be lowered, a convective heat transfer coefficient has to be improved, or a conduction heat resistance from the device to the cooling fluid has to be reduced. However, the cooling fluid temperature that the cooling system may supply to the power module is limited.

To solve this problem, an indirect cooling method that configures a heat dissipation path of a power module by using a thermal grease layer and a base plate layer to increase flow rate or a method of optimizing the shape of a cooler to improve a convective heat transfer coefficient have been used but have limitations in coping with the increased calorific value.

Accordingly, a direct cooling method that reduces thermal resistance by removing the thermal grease layer and the base plate layer may be applied, but it is not effective due to the low cooling performance and cooling efficiency, and in the case of a pin-fin type direct cooling power module, it is bulkier than a double side cooling (DSC) type and double-side cooling is impossible.

### SUMMARY

The present disclosure is directed to solving the above-mentioned problems.

An aspect of the present disclosure provides a cooling device for a power module that reduces heat resistance and also increases a cooling efficiency of a direct cooling method by securing a heat dissipation area and forming a cooling passage for a cooling fluid to contact (e.g., collide with) a surface of a double bonded copper (DBC) heat dissipating board.

An aspect of the present disclosure also provides a cooling device for a power module that may prevent deterioration of heat dissipation performance that may occur due to an excessive amount of cooling fluid by preventing the flow rate of the cooling fluid from being (e.g., excessively) distributed at an outlet.

Objects of the present disclosure are not limited to the above-mentioned objects, and other objects and improvements of the present disclosure not mentioned may be understood from the following description and example embodiments of the present disclosure. In addition, objects and improvements of the present disclosure may be realized from the claims.

According to an aspect of the present disclosure, a cooling device for a power module may include a power module. The power module may include a plurality of power semiconductor elements mounted on an upper surface of a heat dissipating board. The power module may also include a manifold having an inlet and an outlet, in which a heat dissipating space part (e.g., heat dissipating space device), an upper portion of which is exposed to an outside, is formed, in which a flow channel, through which a cooling fluid flows, is formed in an interior thereof, and having a channel passage, in which a portion of the flow channel passing through the heat dissipating space part is formed to be opened to an upper side of the heat dissipating space part, and a heat dissipating member interposed between the power module and the flow channel of the heat dissipating space part while contacting them. The power module further may include a cooling fin module with a plurality of fin members disposed along a lengthwise direction of the manifold. The flow channel may be formed to become narrower from the inlet toward the outlet of the manifold in the heat dissipating space part.

According to an example embodiment of the present disclosure, a portion of the channel passage may include a branch hole branched toward the heat dissipating member. Another portion (e.g., the remaining portions) of the channel passage may include a discharge hole branched from the branch hole, and (e.g., through which) a cooling fluid contacting the heat dissipating member returns to be discharged.

According to an example embodiment of the present disclosure, the channel passage including the branch hole may be formed to have a larger width at a position, in which the power semiconductor element is concentrated.

According to an example embodiment of the present disclosure, the heat dissipating member may be partially connected to implement a form of one module in a state, in which the fin members having a plurality of “U” shapes having a (e.g., specific) length are disposed to be spaced apart from each other by a specific interval.

According to an example embodiment of the present disclosure, the fin members may include a first fin and a second fin having facing plate shapes, a first connection fin integrally connected to upper ends of the first fin and the second fin, and a second connection fin partially connected to lower ends of the first fin and the second fin.

According to an example embodiment of the present disclosure, the first connection fin and the second connection fin may be disposed to be alternately connected to upper ends and lower ends of the first fin and the second fin.

According to an example embodiment of the present disclosure, the flow channel may be formed to be inclined from the inlet toward the outlet of the manifold in the heat dissipating space part.

According to an example embodiment of the present disclosure, the first fin and the second fin may be formed to be curved in directions, in which the fin members face each other such that the first fin and the second fin are buckled by compressive stress as a buckling load is applied to the fin members.

### BRIEF DESCRIPTION OF THE DRAWINGS

The above and other objects and features of the present disclosure will be more apparent from the following detailed description taken in conjunction with the accompanying drawings:

FIG. 1 is a perspective view illustrating a cooling device for a power module according to an example embodiment of the present disclosure;

FIGS. 2 and 3 are exploded perspective views illustrating a cooling device for a power module according to an example embodiment of the present disclosure;

FIG. 4 is an enlarged view of a heat dissipating member of FIG. 2;

FIG. 5 is an enlarged view of a heat dissipating member of FIG. 3;

FIG. 6 is a view illustrating a cooling device for a power module according to an example embodiment of the present disclosure;

FIG. 7 is a cross-sectional view taken along line ‘A-A’ of FIG. 1;

FIG. 8 is a cross-sectional view illustrating a flow channel of a cooling device for a power module according to another embodiment of the present disclosure;

FIG. 9 is a view illustrating changes in a width and the number of flow channels of FIG. 7;

FIG. 10 is a cross-sectional view illustrating a heat dissipating member of a cooling device for a power module according to another embodiment of the present disclosure.

### DETAILED DESCRIPTION

Hereinafter, some embodiments of the present disclosure will be described in detail with reference to the accompanying drawings. In adding reference numerals to the components of the drawings, it should be noted that the same components have the same numerals as possible even when they are illustrated on different drawings. In describing embodiments of the present disclosure, detailed descriptions associated with known functions or configurations may be omitted if they may make subject matter of the present disclosure unnecessarily obscure.

Furthermore, in describing components of embodiments of the present disclosure, the terms first, second, A, B, (a), (b), and the like may be used herein. These terms are used to distinguish one component from another component, but do not limit the corresponding components irrespective of the nature, order, or priority of the corresponding components. When it is described that a certain component is “connected to,” “coupled to,” or “electrically connected to” a second component, it should be understood that the component may be (e.g., directly) connected or electrically connected to the second component, but a third component may be “connected”, “coupled” or “electrically connected” between the components.

Hereinafter, a cooling device for a power module according to an example embodiment of the present disclosure will be described in detail with reference to the accompanying drawings.

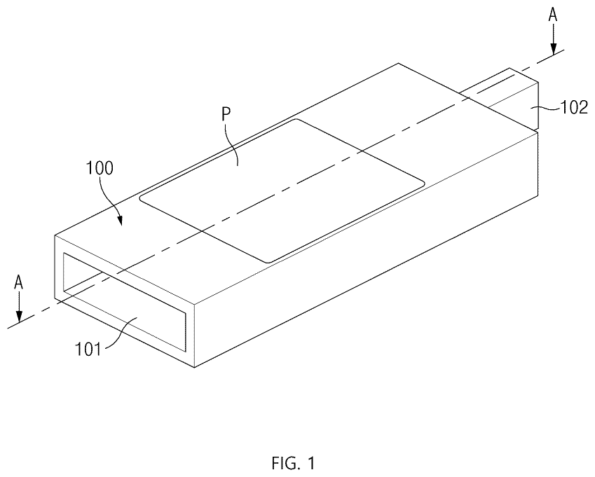

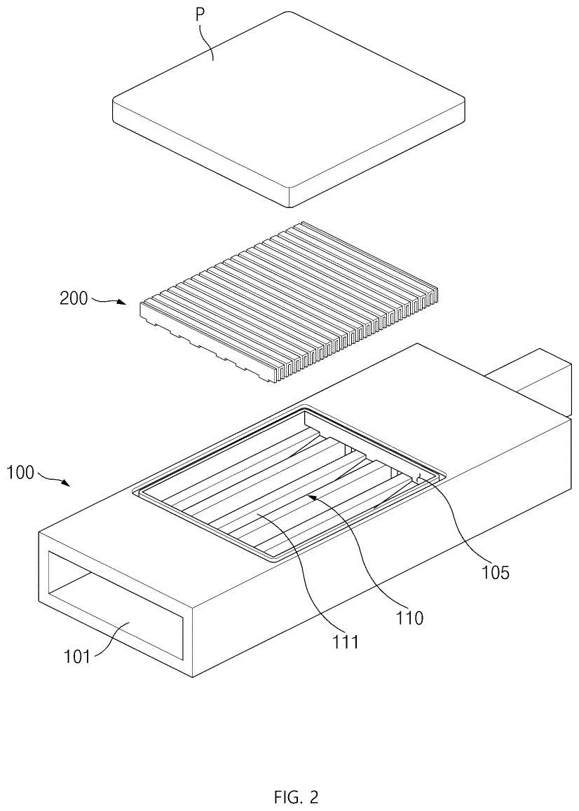

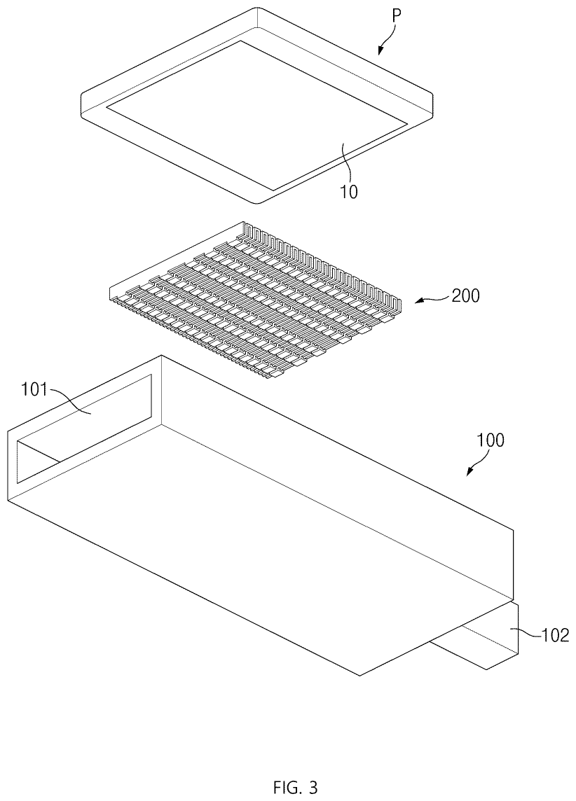

FIG. 1 is a perspective view illustrating a cooling device for a power module according to an example embodiment of the present disclosure, and FIGS. 2 and 3 are exploded perspective views illustrating a cooling device for a power module according to an example embodiment of the present disclosure.

Referring to the figures, FIGS. 1 through 10, the cooling device for a power module “p” according to an example embodiment of the present disclosure may include a manifold 100, to which a power module “p” is coupled, and in which a flow channel 110, through which a cooling fluid flows, is formed, and the power module may further include a heat dissipating member 200 that cools heat emitting power semiconductor elements 20 while contacting the cooling fluid of the manifold 100.

The power module “p” may be configured differently depending on a motor control method, and for example, is a molding structure, in which a circuit pattern formed of a highly conductive metal material, such as copper, is formed on an upper surface of a heat dissipating board 10, and on which a plurality of power semiconductor elements 20, such as IGBTs, which are joined to form an electrical connection while contacting an upper surface of a circuit pattern, are mounted.

The power semiconductor element 20 may be electrically connected to a double bonded copper (DBC) heat dissipating board 10 through a conductive wire, and at least one power semiconductor element 20 is provided, and may include a switching element, such as an insulated gate bipolar transistor (IGBT) and a metal oxide semiconductor field-effect transistor (MOSFET), and a diode.

A lower surface of the power semiconductor element 20 may be joined to an upper surface of the heat dissipating board 10 via an adhesive member (not illustrated).

A thermal interface material (TIM), such as nano silver, which has an adhesive performance and a high thermal conductivity may be applied to the adhesive member, but the present disclosure is not limited thereto, and various materials may be applied. Among the bonding materials (TIMs) used as the adhesive member, materials that are sintered by a constant temperature and a constant pressure or a general solder may be used, and a flatness of the heat dissipating board 10 may be secured by applying a constant temperature and a constant pressure.

The manifold 100 may include an inlet 101, through which a cooling fluid is introduced, and an outlet 102, through which the cooling fluid is discharged. Furthermore, a flow channel 110, through which the cooling fluid flows, is included in an interior of the manifold 100.

The flow channel 110 is formed in the interior of the manifold 100, and an upper portion of the manifold 100 may be opened so that the cooling fluid may be branched upward from a heat dissipating space part 105 that will be described later.

An opened heat dissipating space part 105, into which the heat dissipating member 200 is inserted to perform a heat dissipating function of the power semiconductor element 20 may be formed at an upper portion of the manifold 100, and a lower end of the heat dissipating member 200 inserted into the heat dissipating space part 105 having an opened structure may be exposed to a channel passage 111 of the flow channel 110.

The flow channel 110 includes a plurality of open-topped channel passages 111, and the plurality of channel passages 111 may be disposed along a widthwise direction of the manifold 100 and may be formed to extend from the inlet 101 to the outlet 102 along a lengthwise direction of the manifold 100.

Accordingly, the cooling fluid that flows to the outlet 102 through the inlet 101 of the manifold 100 may be branched toward the heat dissipating member 200 inserted into the heat dissipating space part 105 while passing through the channel passage 111.

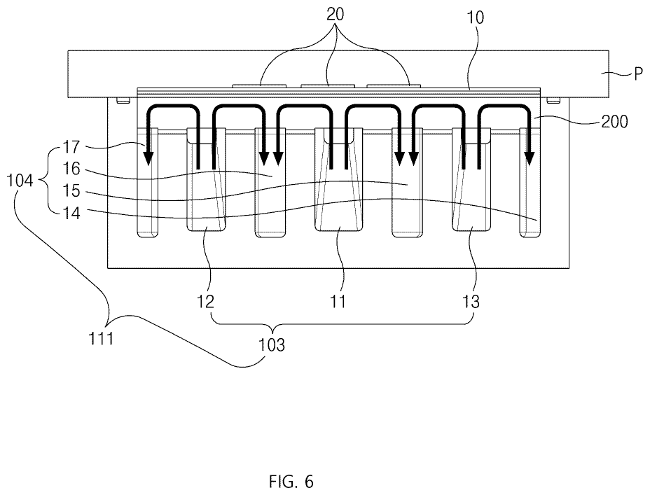

Referring to at least FIG. 6, some of the plurality of channel passages 111 may include a branch hole 103 that is branched toward the heat dissipating member 200, and the remaining ones of the channel passages 111 may include a discharge hole 104, through which the cooling fluid branched from the branch hole 103 and contacting the heat dissipating member 200 returns to be discharged.

As an example embodiment, a first channel passage 11 that is located at the (e.g., dead) center, and a second channel passage 12 and a third channel passage 13 that are (e.g., alternately) disposed on opposite sides of the first channel passage 11 may include the branch hole 103, and the (e.g., remaining) channel passages 14, 15, 16, and 17 may include the discharge hole 104.

Channel passages 111 including the branch hole 103 (e.g., channel passages 111 at positions in which the power semiconductor elements 20 are concentrated) may have a larger width. This provides (e.g., ensures) that a large amount of the cooling fluid is branched to the area, in which the power semiconductor elements 20 are concentrated, so that the heat generated by the power semiconductor elements 20 may be (e.g., rapidly and effectively) radiated to the outside by the heat dissipating member 200. That is, in an example embodiment, the width of the channel passage 111 may increase or decrease in proportion to the number of power semiconductor elements 20.

In an example embodiment, the manifold 100 may be manufactured separately from the flow channel 110, and then may be assembled with the flow channel 110 in the interior of the manifold 100. According to another example embodiment of the present disclosure, the manifold 100 may be manufactured to include the flow channel 110 through injection molding.

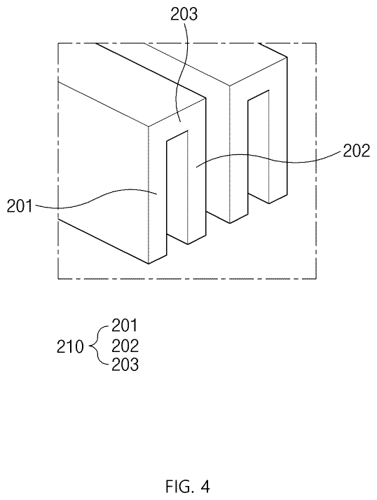

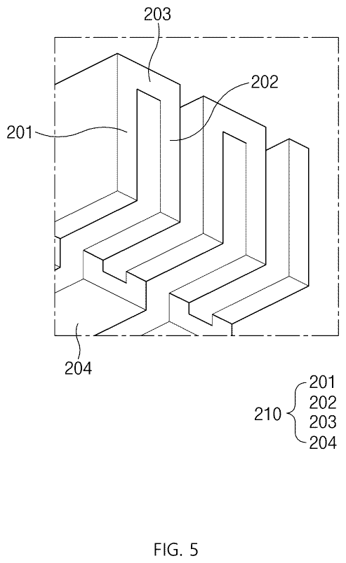

FIG. 4 is an enlarged view of the heat dissipating member 200 of FIG. 2, and FIG. 5 is an enlarged view of the heat dissipating member of FIG. 3.

The heat dissipating member 200 may be interposed in the heat dissipating space part 105 between a lower surface of the heat dissipating board 10 of the power module “p” and the flow channel 110 of the manifold 100. That is, the heat dissipating member 200 may be formed to contact the lower surface of the heat dissipating board 10 of the power module “p” and the opened channel passage 111 of the flow channel 110 installed in the heat dissipating space part 105.

The heat dissipating member 200 may include a cooling fin module, in which a plurality of fin members 210 having a (e.g., specific) shape are disposed along a lengthwise direction of the manifold 100.

The cooling fin module may be partially connected to implement a form of one module in a state, in which the fin members 210 having a plurality of “U” shapes having an (e.g., specific) length are disposed to be spaced apart from each other by an (e.g., specific) interval.

That is, the fin members 210 may include a first fin 201 and a second fin 202 having facing plate shapes, and a first connection fin 203 that is integrally connected to upper ends of the first fin 201 and the second fin 202.

Furthermore, a second connection fin 204 that is partially connected to the lower ends of the first fin 201 and the second fin 202 may be included. In this case, a first connection fin 203 and a second connection fin 204 may be alternately connected to the upper and lower ends of the first fin 201 and the second fin 202, respectively.

In this way, the fin member 210 including the first fin 201, the second fin 202, the first connection fin 203, and the second connection fin 204 may be referred to as a folded-fin, and the heat dissipating member 200 including the cooling fin module may be implemented by modularizing a plurality of folded fins in a state, in which the plurality of folded fins are disposed.

As illustrated in FIG. 4, when the cooling fin module is viewed from a top, an open space may be formed between the fin member 210 and the other fin member 210. Furthermore, as illustrated in FIG. 5, when the cooling fin module is viewed from a bottom, a partially open space may be formed between the fin member 210 and the other fin member 210.

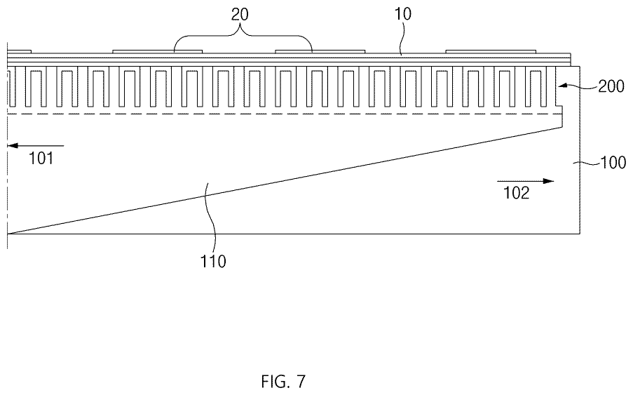

FIG. 7 is a cross-sectional view taken along line ‘A-A’ of FIG. 1.

As illustrated in FIG. 7, a height of the flow channel 110 on a boundary surface of the power module “p” and the heat dissipating member 200 may be sequentially lowered as it goes from the inlet 101 to the outlet 102 of the manifold 100 in the heat dissipating space part 105. That is, the flow channel 110 may be formed to be inclined upward as it goes from the inlet 101 toward the outlet 102 of the manifold 100, and may be formed to become narrower as the flow channel 110 goes toward the outlet 102.

In this way, when the height of the flow channel 110 is changed such that the height of the flow channel 110 decreases as it goes toward the outlet 102, the flow rate of the cooling fluid that flows along the flow channel 110 may be uniformly distributed over the entire flow area of the flow channel 110.

As a result, as the flow rate of the flow channel 110 at the inlet of the heat dissipating space part 105 may be increased more than the flow rate at the outlet side, the flow rate of the cooling fluid may be uniformly distributed throughout the flow area of the flow channel 110, and the heat dissipation performance deterioration problem that may occur due to the excessive distribution of the cooling fluid at the outlet may be reduced and/or solved.

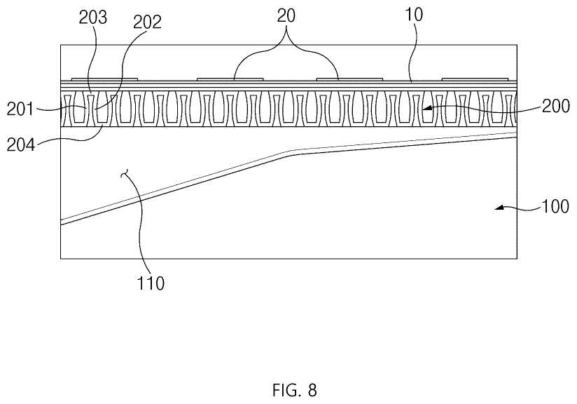

FIG. 8 is a view illustrating the flow channel 110 of a cooling device for a power module according to another embodiment of the present disclosure.

Referring to FIG. 8, unlike FIG. 7, the height of the flow channel 110 at the inlet of the heat dissipating space part 105 may be higher, and the height of the flow channel 110 at the outlet may be lower.

This may further increase the flow rate at the inlet of the flow channel 110 of the heat dissipating space part 105, and further reduce the flow rate of the outlet flow channel 110, thereby reducing a pressure loss of the cooling fluid.

In this way, the pressure loss of the flow channel 110 may be improved by changing the height of the flow channel 110 at the boundary surface of the power module “p” and the heat dissipating member 200.

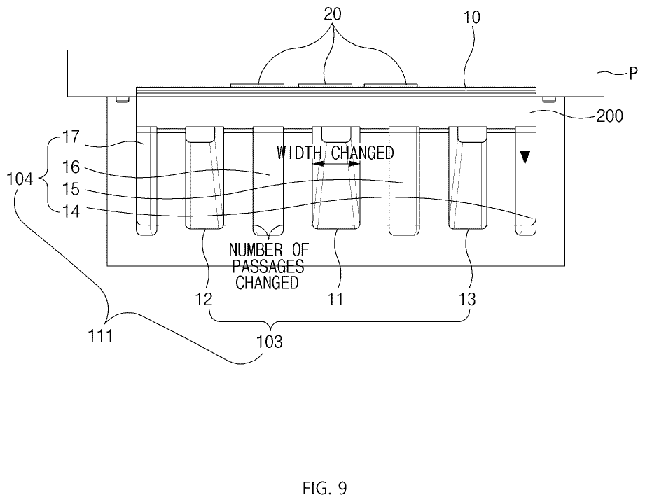

FIG. 9 is a view illustrating changes in width and changes in the number of flow channels 110 of FIG. 7.

Referring to FIG. 9, to improve the pressure loss of the flow channel 110, the width of the flow channel 110 and the number of channel passages 111 may be changed.

In particular, the branch hole 103 of the flow channel 110 may be formed to become narrower as it goes from the inlet 101 to the outlet 102 of the manifold 100 in the heat dissipating space part 105. This is to prevent the flow rate of the cooling fluid from being excessively distributed at the outlet. Accordingly, it is possible to prevent deterioration of the heat dissipation performance that may occur due to an excessive amount of the cooling fluid.

Meanwhile, when the widths of the first fin 201 and the second fin 202 of the fin member 210 of the heat dissipating member 200 are changed to be narrower, a relatively large number of fin members 210 may be disposed within the same area of the heat dissipating space part 105. This increases the heat exchange area, that is, the heat dissipation area, so that the cooling performance may be improved.

Furthermore, when the widths of the first fin 201 and the second fin 202 of the fin member 210 of the heat dissipating member 200 are changed to be larger, a relatively small number of fin members 210 may be disposed within the same area of the heat dissipating space part 105. This decreases the heat exchange area, but the pressure loss may be reduced.

Furthermore, when the height of the flow channel 110 is increased, the heat exchange area may increase and the cross-sectional area of the flow path may increase, so that the flow rate of the cooling fluid that flows through the flow channel 110 is decreased, and thus, the cooling performance may be improved.

The shape and number of such heat dissipating members 200 are not limited to the described embodiments, and may be implemented in various shapes and numbers that are different, and may be implemented by appropriately changing the shape and number depending on the situation of the cooling device for the power module.

Hereinafter, in describing the heat dissipating member 200 according to the second embodiment, a detailed description of a configuration having the same or similar function as that of the configuration of the first embodiment of the present disclosure is omitted to avoid a repeated description.

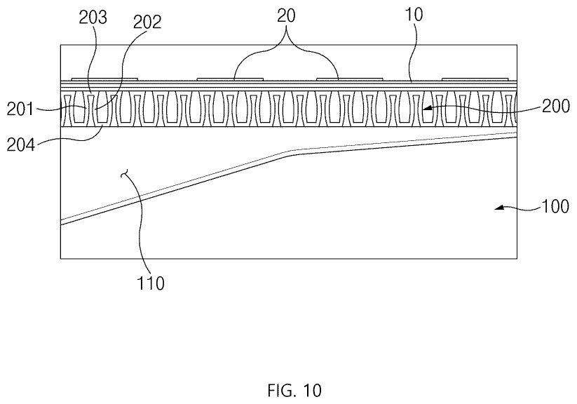

FIG. 10 is a cross-sectional view illustrating the heat dissipating member 200 of a cooling device for a power module according to another embodiment of the present disclosure.

As illustrated in FIG. 10, the heat dissipating member 200 may be formed to contact the lower surface of the heat dissipating board 10 of the power module “p”.

The heat dissipating member 200 may include a cooling fin module, in which fin members 210 having a folded fin shape are disposed along a lengthwise direction of the manifold 100.

In the heat dissipating member 200, the fin members 210 having a plurality of “U” shape fins having a (e.g., specific) length may be partially connected (e.g., to each other) to implement a form of a (e.g., one) module.

That is, the fin members 210 may include a first fin 201 and a second fin 202 that face each other, and a first connection fin 203 is connected to (e.g., upper ends of) the first fin 201 and the second fin 202.

Furthermore, a second connection fin 204 is partially connected to (e.g., the lower ends of) the first fin 201 and the second fin 202 in a state in which a plurality of fin members 210 are disposed at regular intervals may be included.

In this case, the first connection fin 203 and the second connection fin 204 may be alternately connected to the upper and lower ends of the first fin 201 and the second fin 202, respectively.

In this way, the heat dissipating member 200 including a cooling fin module may be implemented by modularizing the plurality of folded fins including the first fin 201, the second fin 202, and the first connection fin 203 and the second connection fin 204 in a state in which they are disposed.

As an example embodiment, the first fin 201 and the second fin 202 may be curved in facing directions. The first connection fin 203 may contact the lower surface of the heat dissipating board 10 of the power module “p”.

According to an example embodiment of the present disclosure, a load that is suitable for sealing is applied to prevent problems caused by the assembly tolerance when the fin member 210 of the heat dissipating member 200 and the lower surface of the heat dissipating board 10 of the power module “p” contact each other during assembly. However, because the fin member 210 of the heat dissipating member 200 and the lower surface of the heat dissipating board 10 of the power module “p” may not accurately contact each other, a gap may occur between them, and the sealing performance may deteriorate due to the gap.

Accordingly, in an example embodiment of the present disclosure, a buckling load is applied to the fin member 210 of the heat dissipating member 200 so that the first fin 201 and the second fin 202 in the curved state may be curved further in the direction that faces each other. Accordingly, the fin member 210 exhibits a damping performance. That is, as a buckling load is applied to the fin member 210 of the heat dissipating member 200, a buckling phenomenon may occur, in which the fin member 210 is curved in a direction, in which the first fin 201 and the second fin 202 face each other by a compressive stress.

Accordingly, as the fin member 210 with a damping performance is effectively attached to the lower surface of the heat dissipating board 10 of the power module “p”, a flatness may be secured between the power module “p” and the heat dissipating member 200.

Accordingly, it is possible to prevent degradation of the sealing performance that may occur due to a gap between the power module “p” and the heat dissipating member 200.

In this case, because the buckling load applied to the fin member 210 varies depending on the cross-sectional area of the fin member 210, the width of the fin member 210 may be appropriately changed.

Accordingly, the present disclosure reduces a heat resistance and also increases the cooling efficiency of the direct cooling method by securing the heat dissipation area and forming the cooling passage that allows the cooling fluid to collide with the surface of the DBC heat dissipating board 10.

According to the cooling device for a power module according to the present disclosure, when the power module is (e.g., directly) cooled, the rated current of the power semiconductor element may be reduced to reduce the size of the power semiconductor element, and thus, costs may be reduced.

The present disclosure also may prevent deterioration of a heat dissipation performance that may occur due to an excessive amount of a cooling fluid by preventing the flow rate of the cooling water from being excessively distributed at the outlet.

According to the present disclosure, when the cooling performance is improved, an operation at a temperature that is lower than an operation temperature according to an existing operation method may be provided, and thus degradation of the durability of the power module may be prevented, and the life may be improved.

Disclosed is a cooling device for a power module that reduces a heat resistance and increases a cooling efficiency of a direct cooling method by securing a heat dissipation area and forming a cooling passage that allows a cooling fluid to collide with a surface of a DBC heat dissipating board.

The above-mentioned description of the present disclosure is intended to be illustrative, and it should be understood by those skilled in the art that the present disclosure may be embodied in other specific forms without departing from the characteristics thereof. Therefore, the above-described embodiments are examples, and should be construed not to be restrictive. The scope of the present disclosure is provided by the claims, and it should be interpreted that the scope of the present disclosure may include modifications and/or changes.

What is claimed is:

1. A cooling device for a power module, comprising:
a power module including a plurality of power semiconductor elements mounted on an upper surface of a heat dissipating board;
a manifold having an inlet and an outlet;
a heat dissipating space device with an upper portion exposed to an outside;
a flow channel formed within an interior of the manifold for cooling fluid to flow within the flow channel, wherein a portion of the flow channel passes through the heat dissipating space device; and
a heat dissipating member is disposed between the power module and the flow channel, wherein the flow channel in the heat dissipating space device narrows between the inlet and the outlet of the manifold.

2. The cooling device of claim 1, wherein the flow channel includes a channel passage including a branch hole branched toward the heat dissipating member.

3. The cooling device of claim 2, wherein the channel passage includes a discharge hole branched from the branch hole, wherein a cooling fluid contacting the heat dissipating member returns to be discharged through the discharge hole.

4. The cooling device of claim 3, wherein the channel passage including the branch hole is formed with a width, wherein the width is wider at a position in which the power semiconductor elements are concentrated.

5. The cooling device of claim 1, wherein the heat dissipating member includes a cooling fin module.

6. The cooling device of claim 5, wherein the cooling fin module includes a plurality of fin members disposed along a lengthwise direction of the manifold.

7. The cooling device of claim 6, wherein at least one fin member of the plurality of fin members has a U-shape.

8. The cooling device of claim 7, wherein the at least one fin member with the U-shape has a length and is spaced apart by an interval from another fin member with a U-shape.

9. The cooling device of claim 6, wherein the fin members include a first fin and a second fin having facing plate shapes.

10. The cooling device of claim 9, wherein the fin members include a first connection fin integrally connected to an upper end of the first fin and an upper end of the second fin.

11. The cooling device of claim 10, wherein the fin members include a second connection fin connected to a lower end of the first fin and a lower end of the second fin.

12. The cooling device of claim 11, wherein the first connection fin is alternately disposed with the second connection fin.

13. The cooling device of claim 12, wherein the first fin and the second fin are curved in directions in which the fin members face each other.

14. The cooling device of claim 13, wherein the first fin and the second fin are buckled by compressive stress as a buckling load is applied to the fin members.

15. The cooling device of claim 1, wherein the flow channel is inclined between the inlet and the outlet of the manifold in the heat dissipating space device.

16. The cooling device of claim 1, wherein the portion of the flow channel passing through the heat dissipating space device is open to an upper side of the heat dissipating space device.

17. The cooling device of claim 1, wherein the heat dissipating member is configured to cool the plurality of power semiconductor elements while contacting the cooling fluid of the manifold.

18. The cooling device of claim 1, wherein a lower surface of at least one power semiconductor element of the plurality of power semiconductor elements is joined to the upper surface of the heat dissipating board with an adhesive member.

19. The cooling device of claim 1, wherein a lower end of the heat dissipating member is configured to be inserted into the heat dissipating space device.

20. The cooling device of claim 1, wherein the heat dissipating board is a double bonded copper heat dissipating board.
